(19) United States
(12) Patent Application Publication
(10) Pub. No.: US 2012/0026807 A1
(43) Pub. Date: Feb. 2, 2012

(54) SEMICONDUCTOR MEMORY CHIP AND INTEGRATED CIRCUIT

(75) Inventors: Hyun Seok KIM, Icheon-si Gyeonggi-do (KR); Sung Woo HAN, Icheon-si Gyeonggi-do (KR); Jun Ho LEE, Suwon-si Gyeonggi-do (KR); Boo Ho JUNG, Daegu-si (KR); Yang Hee KIM, Icheon-si Gyeonggi-do (KR)

(73) Assignee: HYNIX SEMICONDUCTOR INC., Icheon-si (KR)

(21) Appl. No.: 13/012,497

(22) Filed: Jan. 24, 2011

(30) Foreign Application Priority Data
Mar. 30, 2010 (KR) 10-2010-0028716

(51) Int. Cl. G11C 5/14; G11C 7/00

(52) U.S. Cl. 365/189.09; 365/198

(57) ABSTRACT

A semiconductor memory chip includes: a driving voltage reception unit configured to receive a power supply voltage and a ground voltage; a first data driving unit configured to be supplied with the power supply voltage and the ground voltage, and drive first data to output the driven first data through a first data line; a second data driving unit configured to be supplied with the power supply voltage and the ground voltage, and drive second data to output the driven second data through a second data line; and a MOS transistor coupled between the first data line and the second data line.

### CROSS-REFERENCES TO RELATED APPLICATIONS

The present application claims priority under 35 U.S.C 119(a) to Korean Application No. 10-2010-0028716, filed on Mar. 30, 2010, in the Korean intellectual property Office, which is incorporated herein by reference in its entirety.

### BACKGROUND

A semiconductor package refers generally to a packaged semiconductor memory chip with fine circuits sealed with a mold resin or ceramic for protection from external environments and mounting on an integrated circuit. Additional emphases were also put on the semiconductor packaging design to improve the performance and quality of the integrated circuit through compactness, slimness, and multi-functionality.

Achieving all of compactness, slimness, and multi-functionality of electronic devices requires reducing the size while increasing the capacity of a semiconductor chip. One suitable technique is known as a chip scale packaging, which requires that the package must have a size no greater than 1.2 times the size of the semiconductor memory chip. Other areas of interest in the semiconductor packaging focus on increasing capacity and processing speed of a semiconductor package.

FIG. 1 shows a conventional integrated circuit including a semiconductor memory chip formed in a semiconductor package.

In the conventional integrated circuit of FIG. 1, data outputted from the semiconductor memory chip in a semiconductor package are transferred to a first transmission line TL1 and a second transmission line TL2 through a first package data line PDL1 and a second package data line PDL2 formed in the package area. Since the first and second transmission lines TL1, TL2 have equivalent inductances, a mutual inductance ML occurs between the first and second transmission lines TL1, TL2. The mutual inductance ML causes signal noise due to crosstalk in the data signal transferred through the first and second transmission lines TL1, TL2.

To solve this problem, the conventional integrated circuit utilizes a coupling capacitor CP between the first and second package data lines PDL1, PDL2 in order to offset the mutual inductance ML between the first and second transmission lines TL1, TL2. However, the coupling capacitor CP has an equivalent series inductance ESL, which serves as a limiting factor of the integrated circuit operating in a wide bandwidth.

### SUMMARY

An embodiment of the present invention provides a semiconductor memory chip and an integrated circuit, which are capable of operating in a wide bandwidth by providing a coupling capacitor implemented with a MOS transistor within the semiconductor memory chip.

In an embodiment, a semiconductor memory chip includes: a driving voltage reception unit configured to receive a power supply voltage and a ground voltage; a first data driving unit configured to be supplied with the power supply voltage and the ground voltage, and drive first data to output the driven first data through a first data line; a second data driving unit configured to be supplied with the power supply voltage and the ground voltage, and drive second data to output the driven second data through a second data line; and a MOS transistor coupled between the first data line and the second data line.

In another embodiment, an integrated circuit includes: a semiconductor memory chip in which a MOS transistor operating as a coupling capacitor is coupled between first and second data lines through which first and second data are outputted; and first and second package data lines provided in a package area of the semiconductor memory chip and configured to transfer data from the first and second data lines to first and second transmission lines which are coupled to a memory control unit.

### BRIEF DESCRIPTION OF THE DRAWINGS

The above and other aspects, features and other advantages will be more clearly understood from the following detailed description taken in conjunction with the accompanying drawings, in which:

FIG. 1 shows a conventional integrated circuit including a semiconductor memory chip in which a semiconductor package is formed;

FIG. 2 shows an integrated circuit according to an embodiment of the present invention;

FIG. 3 is a circuit diagram of the integrated circuit shown in FIG. 2; and

FIG. 4 is a waveform diagram for explaining signal noise attenuation effect of the integrated circuit shown in FIG. 2.

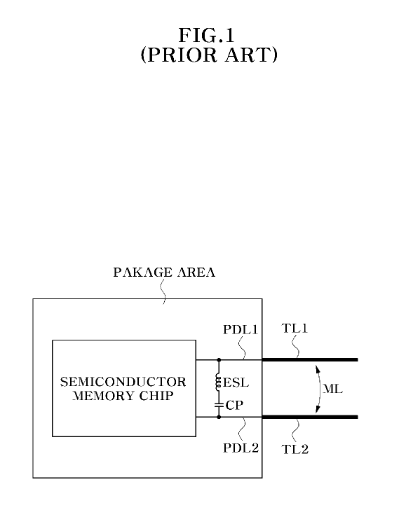

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

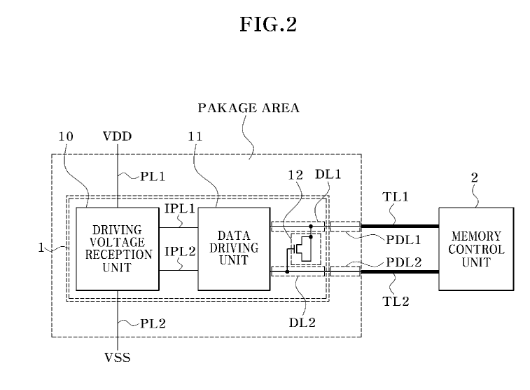

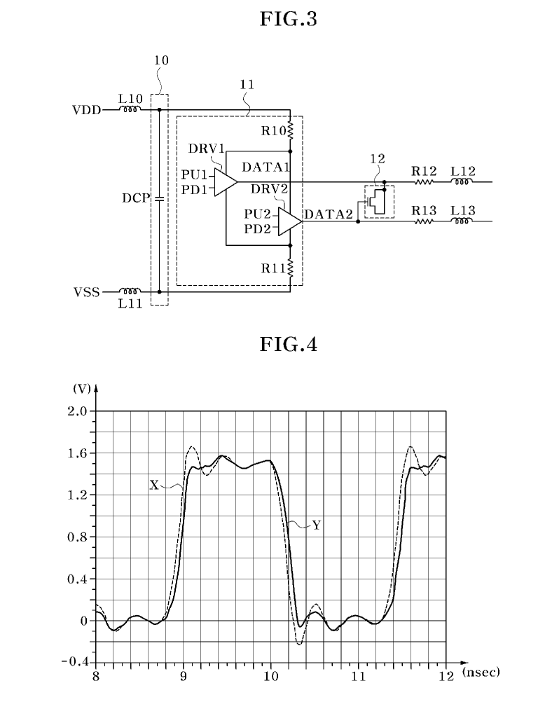

FIG. 2 illustrates a structure of an integrated circuit according to an embodiment of the present invention, and FIG. 3 is a circuit diagram of the integrated circuit illustrated in FIG. 2.

Referring to FIG. 2, the integrated circuit according to an embodiment of the present invention includes a semiconductor memory chip 1, first and second package data lines PDL1, PDL2 in a package area, and first and second transmission lines TL1, TL2 outside the package area. Data are transferred from the semiconductor memory chip 1 to a memory control unit 2 through the first and second package data lines PDL1, PDL2 and the first and second transmission lines TL1, TL2, respectively.

The semiconductor memory chip 1 includes a driving voltage reception unit 10, a data driving unit 11, and a coupling capacitor 12 coupled between first and second data lines DL1, DL2.

The driving voltage reception unit 10 is configured to receive a power supply voltage VDD and a ground voltage VSS through a first power line PL1 and a second power line PL2, respectively, in the package area. The driving voltage reception unit 10 is also configured to provide the received voltages VDD and VSS to the data driving unit 11. The first and second power lines PL1, PL2 have inductances in the lines, and their equivalent inductances are represented as L10, L11, respectively, in FIG. 3.

Referring back to FIG. 2, the power supply voltage VDD is supplied to the data driving unit 2 from the first power line PL1 and correspondingly through a first internal power line IPL1. Likewise, the ground voltage VSS is supplied to the data driving unit 2 from the second power line PL2 and through a second internal power line IPL2. As shown in FIGS. 2-3, the data driving unit 11 drives first and second data DATA1, DATA2 to output through the first and second data lines DL1, DL2, respectively. More specifically, referring to FIG. 3, the data driving unit 11 includes first and second data drivers DRV1, DRV2. The first data driver DRV1 is configured to receive a first pull-up signal PU1 and a first pull-down signal PD1 and drive the first data DATA1, and the second data driver DRV2 is configured to receive a second pull-up signal PU2 and a second pull-down signal PD2 and drive the second data DATA1. The equivalent resistances in the first and second internal power lines IPL1 and IPL2 are represented as first and second resistors R10, R11, respectively.

The coupling capacitor 12 is implemented with an NMOS transistor with its source and drain coupled to the first data line DL1 and its gate coupled to the second data line DL2. Alternatively, the coupling capacitor 12 may be formed by coupling the source and drain of the NMOS transistor to the second data line DL2 and the gate to the first data line DL1.

Since the coupling capacitor 12 is implemented with the NMOS transistor, an equivalent series inductance (ESL) does not occur as opposed to the conventional coupling capacitor formed in the package area. Consequently, the integrated circuit to which the coupling capacitor 12 is applied according to an embodiment of the present invention may be stably operated in a wide bandwidth.

The equivalent resistances of the first and second package data lines PDL1, PDL2 are represented with third and fourth resistors R12, R13, respectively. The equivalent inductances of the first and second package data lines PDL1, PDL2 are represented with third and fourth inductors L12, L13.

The coupling capacitor 12 having the NMOS transistor in the integrated circuit according to an embodiment of the present invention may control the capacitance in units of several pF by adjusting the width and length of the gate. Therefore, by adjusting the capacitance of the coupling capacitor 12, it is possible to attenuate signal noise generated by crosstalk between the data signals transferred through the first and second transmission lines TL1, TL2.

As shown in FIG. 4, in the case X when the coupling capacitor 12 is not implemented, overshooting occurs in the waveform of the data signals transferred through the first and second transmission lines TL1, TL2. On the contrary, in the case Y when the coupling capacitor 12 is implemented in the integrated circuit according to an embodiment of the present invention, overshooting of X is quite improved.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A semiconductor memory chip provided with a power supply voltage and a ground voltage comprising:
a first data driving unit provided with the power supply voltage and the ground voltage and configured to drive first data to output the driven first data through a first data line;
a second data driving unit provided with the power supply voltage and the ground voltage and configured to drive second data to output the driven second data through a second data line; and
a MOS transistor coupled between the first data line and the second data line.

2. The semiconductor memory chip of claim 1, further comprising a driving voltage reception unit configured to receive the power supply voltage and the ground voltage and provide the power supply voltage and the ground voltage to the first and second data driving units.

3. The semiconductor memory chip of claim 2, wherein the driving voltage reception unit comprises a capacitor coupled between a power supply voltage transmission medium including a terminal and a ground voltage transmission medium including a terminal.

4. The semiconductor memory chip of claim 2, wherein components comprising the driving voltage reception unit and the first and second data driving units are packaged, and wherein the power supply voltage and the ground voltage are provided to the first and second data driving units through power lines provided in the package.

5. The semiconductor memory chip of claim 1, wherein the first data driving unit drives the first data in response to a first pull-up signal and a first pull-down signal.

6. The semiconductor memory chip of claim 1, wherein the second data driving unit drives the second data in response to a second pull-up signal and a second pull-down signal.

7. The semiconductor memory chip of claim 1, wherein the MOS transistor operates as a coupling capacitor.

8. The semiconductor memory chip of claim 7, wherein at least one of the source and drain of the MOS transistor is coupled to the first data line, and the gate of the MOS transistor is coupled to the second data line.

9. The semiconductor memory chip of claim 7, wherein at least one of the source and drain of the MOS transistor is coupled to the second data line, and the gate of the MOS transistor is coupled to the first data line.

10. An integrated circuit comprising:
a package comprising a semiconductor memory chip configured to output first and second data through first and second package data lines;
a memory control unit; and
first and second transmission lines for transferring the first and second data from the first and second package data lines to the memory control unit,
wherein the semiconductor memory chip comprises:
first and second data lines for transferring the first and second data to the first and second package data lines; and
a capacitive element coupled between the first and second data lines configured to provide a coupling capacitance.

11. The integrated circuit of claim 10, wherein the semiconductor memory chip is provided with a power supply voltage and a ground voltage and further comprises:
a first data driving unit provided with the power supply voltage and the ground voltage and configured to drive the first data to output the driven first data through the first data line; and
a second data driving unit provided with the power supply voltage and the ground voltage and configured to drive the second data to output the driven second data through the second data line.

12. The integrated circuit of claim 11, wherein the semiconductor memory chip further comprises a driving voltage reception unit configured to receive the power supply voltage and the ground voltage and provide the power supply voltage and the ground voltage to the first and second data driving units.

13. The integrated circuit of claim 12, wherein the driving voltage reception unit comprises a capacitor coupled between a power supply voltage transmission medium including terminal and a ground voltage transmission medium including a terminal.

14. The integrated circuit of claim 12, wherein the power supply voltage and the second ground voltage are provided to the first and second data driving units through power lines provided in the package.

15. The integrated circuit of claim 12, wherein the first data driving unit drives the first data in response to a first pull-up signal and a first pull-down signal.

16. The integrated circuit of claim 12, wherein the second data driving unit drives the second data in response to a second pull-up signal and a second pull-down signal.

17. The integrated circuit of claim 10, wherein at least one of the source and drain of the MOS transistor is coupled to the first data line, and the gate of the MOS transistor is coupled to the second data line.

18. The integrated circuit chip of claim 10, wherein at least to one of the source and drain of the MOS transistor is coupled to the second data line, and the gate of the MOS transistor is coupled to the first data line.
